(19) United States
(12) Patent Application Publication
(10) Pub. No.: US 2015/0194515 A1
(43) Pub. Date: Jul. 9, 2015

(54) Programmable antenna controlled impedance mosfet

(71) Applicant: Kelly James Heily, Santa Clara, CA (US)

(72) Inventor: Kelly James Heily, Santa Clara, CA (US)

(21) Appl. No.: 14/120,452

(22) Filed: Jan. 6, 2014

(51) Int. Cl. H01L 29/78; H01L 23/64; H01L 29/10

(52) U.S. Cl. CPC H01L 29/78; H01L 29/1033; H01L 23/64; H01L 2223/6688

(57) ABSTRACT

Hop frequency radio technologies use dynamic modulation frequency control through a single antenna with non-ideal performance as antenna length is inversely proportional to modulation frequency. The Programmable Antenna Controlled Impedance Mosfet is a digitally controlled variable length antenna that can be used to maximize power and bandwidth efficiencies in hop frequency applications.

### INVENTION BACKGROUND

Modern day radio communications utilize frequency hopping to maximize bandwidth via transceivers configured for real time signal to noise ratio feedback and dynamic modulation frequency control. Energy and bandwidth efficiencies are maximized when transceiver output impedance matches antenna impedance and modulation frequency induces resonance in the antenna and its matching network. The Programmable Antenna Controlled Impedance Mosfet optimizes efficiency for all hopping frequencies.

### DESCRIPTION OF FIGURES

FIG. 1 shows the terminal connections and semi-conductor doping for an unbiased n-channel enhancement mode mosfet.

FIG. 2 shows an enhanced n-channel Mosfet with a single Gate structure.

FIG. 3 shows an enhanced n-channel Mosfet with two active Gate segments and maximum channel length.

FIG. 4 shows an enhanced n-channel Mosfet with one of two active Gate segments and ½ maximum channel length.

FIG. 5 shows the schematic symbol for the Programmable Antenna Controlled Impedance Mosfet.

### INVENTION DESCRIPTION

Semiconductors utilize silicon doping to provide both low conductance and high conductance regions to control current. Doped silicon is commonly denoted as either n-type or p-type. A low conductance p-type semi-conductor is created by doping the silicon crystal with an impurity that accepts electrons. A high conductance n-type semi-conductor is created by doping the silicon crystal with an impurity that contributes electrons.

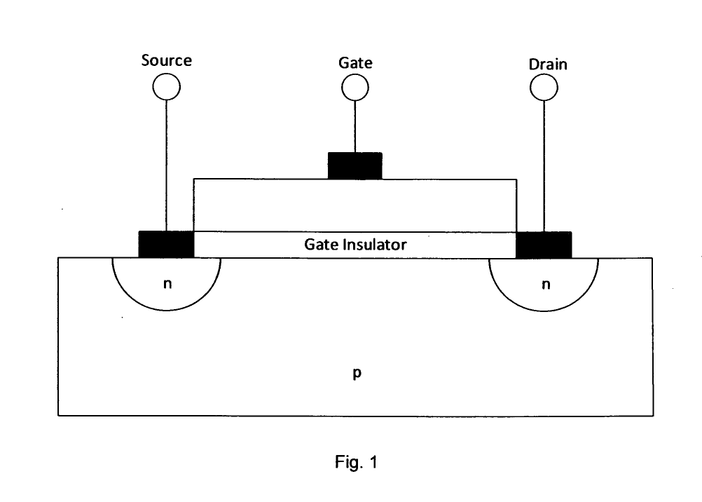

An n-channel metal-oxide semi-conductor field effect transistor (Mosfet) is a three terminal device that can be used either as a switch or amplifier element providing voltage control of the Drain to Source current via the Gate to Source voltage. The Drain and Source are directly tied to conductive n-type semi-conductors while the Gate is indirectly tied to a non-conductive p-type semi-conductor through a Gate Insulator (FIG. 1).

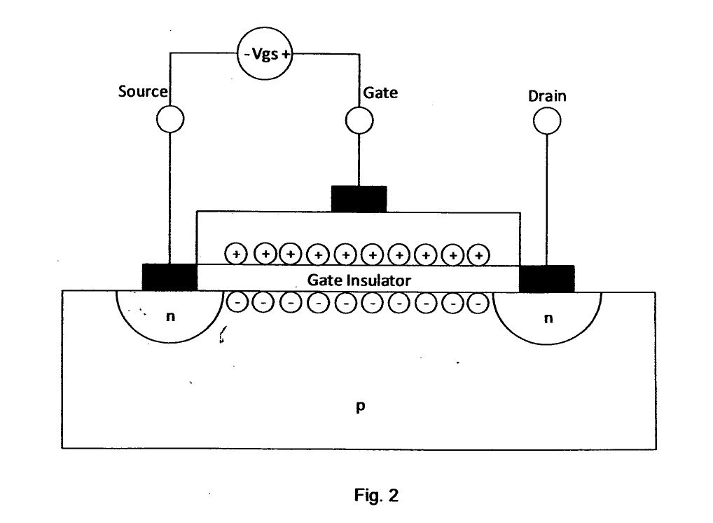

The Drain to Source conductivity is increased by applying a positive voltage between the Gate and Source terminals. The Gate to Source voltage produces an electric field which enhances a channel with the available p-type semi-conductor electrons drawn towards the Gate insulator lowering the Drain to Source impedance. The Drain to Source conductivity is increased as the Gate to Source voltage is increased to its threshold voltage. A programmable switch is possible using the n-channel Mosfet with a digitally compatible threshold voltage (FIG. 2).

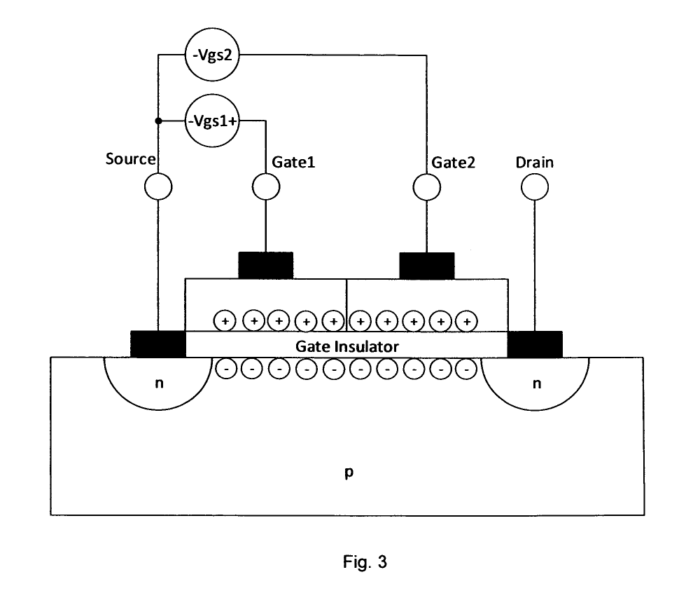

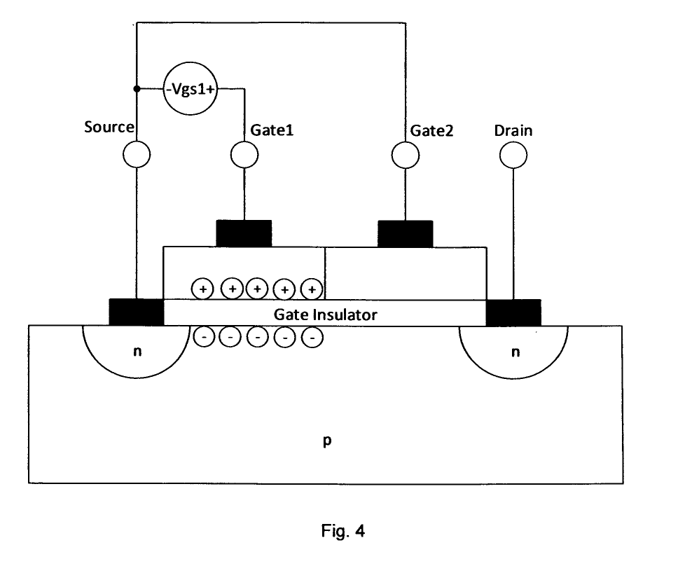

The conductive enhancement of the p-type semi-conductor material in the n-channel Mosfet is traditionally accomplished with a single controlling Gate input for controlling the drain to source current (FIG. 2). Further control of the enhancement region can be gained by adding another Gate input (FIG. 3). If the two controlling Gates are of equal dimension the length of the enhancement region can be halved by shorting the second Gate to the Source (FIG. 4).

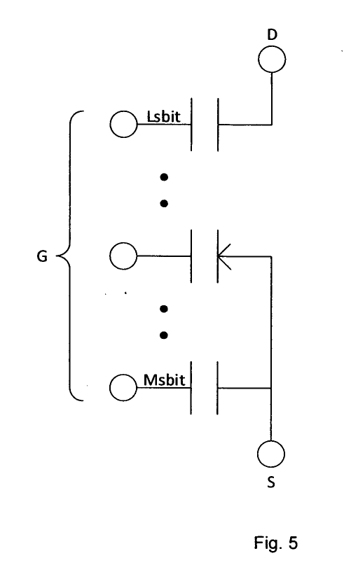

The Programmable Antenna Controlled Impedance Mosfet consists of a n-channel mosfet configured with multiple gate inputs for digitally controlling the enhancement channel length (FIG. 5).

A monopole antenna is commonly used in conjunction with frequency hopping radio transceivers with an optimal length of ¼ the modulation frequency wavelength. Maximum efficiency requires discrete antenna lengths and for each modulation frequency the length is equal to;

$$Lgth = \frac{c}{4 [ ( f min + ( n\_hop - 1 ) Δ hop ]}$$

$$Δ hop = \frac{f max - f min}{n - 1}$$

Where c is the speed of light, fmin is the minimum hop frequency, fmax is the maximum hop frequency, and n_hop is the hop frequency number with 1 representing the lowest frequency and n representing the highest frequency.

The characteristic impedance for a uniform transmission line is defined by;

$$Zc = \sqrt{\frac{L}{C}}$$

Where L is the inductance per unit length and C is the capacitance per unit length.

Inductance and Capacitance can be calculated as follows;

$${V}_{L} = N \frac{d φ}{d t} = {NA}_{c} \frac{d b}{d t} = L \frac{d i}{d t}$$

$${NA}_{c} \int d b = L \int d i$$

$$L = \frac{{NA}_{c} B ( t )}{i ( t )} = \frac{{NA}_{c} {μ}_{0} {μ}_{r} H ( t )}{i ( t )}$$

$$L = ∮ \overline{H ( t )} \cdot \overline{d l} = Ni ( t )$$

$$i ( t ) = \frac{H ( t ) {I}_{m}}{N}$$

$$L = \frac{{N}^{2} {A}_{c} {μ}_{0} {μ}_{r}}{{I}_{m}}$$

L=Inductance
N=Magnetic Field Producing Turns
A_{c}=Magnetic Field Area (Core Area)
Iₘ=Magnetic Field Path Length (Core Length)
μ₀=Free Space Permeability
μᵣ=Core Relative Permeability

$$C = \frac{{A}_{p} {0}_{} {r}_{}}{d}$$

C=Capacitance
Ap=Capacitance Plate Area
d=Plate Seperation Distance
[symbol] ₀=Free Space Permittivity
[symbol] ᵣ=Dielectric Relative Permittivity

The Programmable Antenna Controlled Impedance Mosfet is source driven, connected to the transceiver through a balun, and is digitally controlled via n Gate inputs where n is the number of hopping frequencies. The Gate inputs require low impedance drivers to minimize antenna loading. For isolated gate drive applications the antenna width (W_{dth}) is calculated as a function of the transceiver output resistance (R_{xcvr}) and the distance (d) to a “Phantom Ground Plane” as follows;

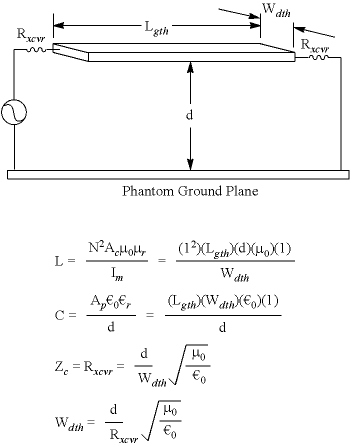

This calculation is done as if the antenna were terminated into the “Phantom Ground Plane” with uniform characteristic impedance over the length of the antenna.

Non-isolated gate drive applications have to account for additional gate capacitance which loads the antenna. The antenna width (W_{dth}) is then calculated as a function of the transceiver output resistance (R_{xcvr}), the distance (d), the gate oxide relative permittivity ( [symbol] _{rg}), and the gate oxide thickness (d_{g}) as follows;

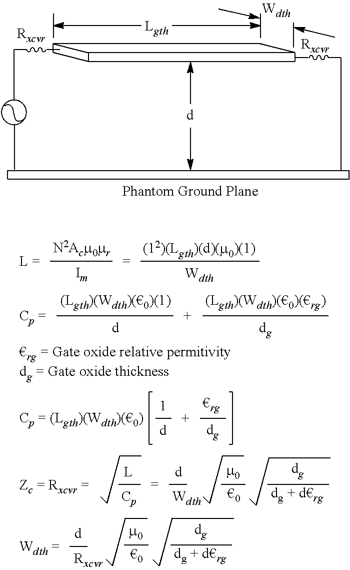

The maximum enhanced channel length is produced with all gates digitally driven over the Gate to Source threshold voltage. The gate function for a Bluetooth Low Energy application is as follows;

$$\begin{matrix}n\_hop & G ( Hex ) \\ 1 & FFFFFFFFFF \\ 2 & FFFFFFFFFE \\ 3 & FFFFFFFFF 8 \\ 4 & FFFFFFFFF 0 \\ ⋮ & ⋮ \\ 40 & 8000000000\end{matrix}$$

What is claimed:

1. A Programmable Antenna Controlled Impedance Mosfet comprised of:
an n-channel enhancement mode semi-conductor doping and pin-out;
a Drain to Source maximum enhanced channel length as determined by the lowest application modulation frequency;
a set of n Gate segments, spanning the Drain to Source length, to digitally set n enhancement channel lengths per n application hopping frequencies;
a controlled open Drain enhanced channel characteristic impedance matching the application impedance.
